(19) United States
(12) Patent Application Publication
(10) Pub. No.: US 2008/0157377 A1
(43) Pub. Date: Jul. 3, 2008

(54) SEMICONDUCTOR DEVICE AND FABRICATING METHOD THEREOF

(75) Inventor: Cheon Man Shim, Seoul (KR)

Correspondence Address: WORKMAN NYDEGGER, 60 EAST SOUTH TEMPLE, 1000 EAGLE GATE TOWER, SALT LAKE CITY, UT, 84111, US

(73) Assignee: DONGBU HITEK CO., LTD., Seoul (KR)

(21) Appl. No.: 11/932,354

(22) Filed: Oct. 31, 2007

(30) Foreign Application Priority Data
Dec. 29, 2006 (KR) 10-2006-0137303

(51) Int. Cl. H01L 23/52; H01L 21/4763

(52) U.S. Cl. 257/751; 438/627; 257/E21.495; 257/E23.141

(57) ABSTRACT

The present invention relates to a semiconductor device comprising a first wafer comprising an isolating layer formed on a silicon substrate, a barrier metal layer formed on the isolating layer, a first seed layer formed on the barrier metal layer, a first metal layer formed on the first seed layer, a surface of which is cleaned with NE14 or DHF, a barrier dielectric layer formed of SiCN on the first metal layer, a second seed layer formed on the barrier dielectric layer and a second metal layer formed on the second seed layer.

### CROSS-REFERENCE TO RELATED APPLICATIONS

This application claims the benefit of the Korean Patent Application No. 10-2006-0137303, filed on Dec. 29, 2006, which is hereby incorporated by reference in its entirety.

### BACKGROUND OF THE INVENTION

1. Field of the Invention

The present invention relates to a semiconductor device. More particularly, the present invention relates to a semiconductor device with improved adhesion properties.

2. Discussion of the Related Art

In a typical semiconductor manufacturing process known in the art, an electric conductor layer, such as an aluminum (Al) or tungsten (W), is deposited, and formed into a pattern through a photography and dry etching process in order to form the wiring of the semiconductor device.

Recently, the width of the wiring in the semiconductor device has become increasingly narrow, semiconductor devices have been manufactured using metals with low specific resistance properties, such as copper, in order to reduce the RC delay time. In cases where the wiring is formed using copper (Cu), a Damascene process is used because it is difficult to dry etch and form the copper into the appropriate pattern. In addition, when the wiring is formed using copper (Cu), a diffusion barrier layer must be formed on each side of the copper (Cu) in order to prevent the copper from diffusing.

FIG. 1 is a cross-section view of a semiconductor device of the related art. As shown in FIG. 1, the semiconductor device of the related art comprises an isolating layer 4 formed on the silicon substrate 2, a barrier metal layer 6 formed on the isolating layer 4, a first seed layer 8 formed on the barrier metal layer 6, a first metal layer 10 formed on the first seed layer 8, a barrier dielectric layer 12 formed on the first metal layer 10, a second seed layer 14 formed on the barrier dielectric layer, and a second metal layer 16 formed on the second seed layer 14.

Typically, the isolating layer 4 is formed of dioxide (SiO₂) and is deposited at a thickness of 1000 Å.

The barrier metal layer 6 prevents the copper (Cu) of the first metal layer 10 from diffusing into the isolating layer 4. Typically, the barrier metal layer 6 is formed of titan silicon nitride (TiSiN) or in a double structure of tantalum/tantalum nitride (Ta/TaN at a thickness of 150 Å.

The first seed layer 8 and the second seed layer 14 are formed at a thickness of 800 Å, and the first metal layer 10 and the second metal layer 16 are formed of metal material, such as copper (Cu) at a thickness of 1000 Å.

The barrier dielectric layer 12 prevents the diffusion of the copper (Cu) in the first metal layer 10 from diffusing into the other layers of the semiconductor and is formed of silicon nitride (SiN) at a thickness of 500 Å.

After forming the first metal layer 10 on the semiconductor device, the surface of the first metal layer 10 is planarized using a chemical mechanical polishing process, hereinafter referred as to a “CMP” process. Then, the surface of the first metal layer 10 is plasma treated with ammonia (NH₃) in order to remove any residue of the first metal layer 10 before forming the barrier dielectric layer 12.

Generally, silicon nitride (SiN) is used as the barrier dielectric layer, so a plasma treatment is performed on the surface of the first metal layer using NH₃, in order to adhere the first metal layer 10 to the barrier dielectric layer 12

As the line width of the wiring of the semiconductor device becomes increasingly narrow, a material with a low dielectric constant is used in order to reduce RC delay time. Thus, a silicon carbon nitride (SiCN) having low dielectric constant is typically used as the barrier dielectric layer 12 of the semiconductor device. In order to sufficiently join the layers of the device, however, a method of improving the adhesion between the first metal layer 10 and the barrier dielectric layer 12 is needed.

### BRIEF SUMMARY OF THE INVENTION

The object of the present invention is to provide a semiconductor device capable with improved adhesion between the metal layer and the dielectric layer.

In order to accomplish the above stated objects, the present invention relates to a semiconductor device comprising an isolating layer formed on a silicon substrate, a barrier metal layer formed on the isolating layer, a first seed layer formed on the barrier metal layer, a first metal layer formed on the first seed layer, the surface thereof being wet cleaning treated using either NE14 or DHF in order to improve the adhesion between the layers, a barrier dielectric layer formed on the first metal layer being formed of SiCN, a second seed layer formed on the barrier dielectric layer, and a first wafer including a second metal layer formed on the second seed layer.

Another aspect of the invention is a method of forming a semiconductor device, comprising forming an isolating layer on a silicon substrate, forming a barrier metal layer on the isolating layer, forming a first seed layer on the barrier metal layer, forming a first metal layer on the first seed layer, clean-treating a surface of the first metal layer using either NE14 or DHF, forming a barrier dielectric layer of a SiCN material on the first metal layer, forming a second seed layer on the barrier dielectric layer, and forming a first wafer comprising a second metal layer on the second seed layer.

### BRIEF DESCRIPTION OF THE DRAWINGS

The accompanying drawings are included to provide a further understanding of the invention and are incorporated in and constitute a part of this application. The drawings illustrate embodiment(s) of the invention and together with the description serve to explain the principle of the invention. In the drawings:

FIG. 1 is a cross-sectional view illustrating a semiconductor according of the related art;

FIG. 2 is a cross-sectional view showing a semiconductor device according to an embodiment of the present invention;

FIG. 3 is a cross-sectional view showing a bending system for testing the semiconductor device illustrated in FIG. 2;

FIG. 4 is a graph showing the relation between the measured displacement and the load from the bending system illustrated in FIG. 3;

FIG. 5 is a graph showing the interfacial adhesion based on the surface treatment of the first metal layer illustrated in FIG. 2;

FIG. 6 is a graph showing the AES depth profile based on the sputter time in various surface treatment methods on the first metal layer illustrated in FIG. 2; and

FIG. 7 shows a graph of the AES depth profile based on the sputter time in various surface treatment methods on the first metal layer illustrated in FIG. 2.

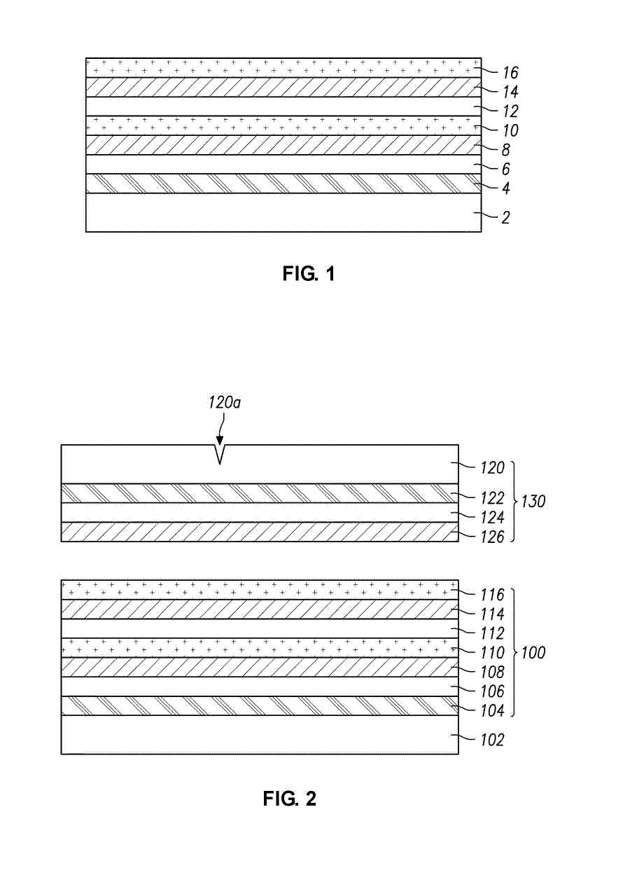

### DETAILED DESCRIPTION OF THE INVENTION

The other objects, features, and advantages of the present invention will be apparent from the detailed description of the embodiments in conjunction with the accompanying drawings.

Hereinafter, while the constitution and effect of the embodiments of the present invention will be described with reference to the accompanying drawings, the constitution and effect of the present invention shown in the drawings and described with reference thereto are described as at least one embodiment of the invention. Therefore, the technical idea, core constitution, scope, and effect of the present invention are not limited to the embodiments shown in the drawings.

The preferred embodiments of the present invention will be described with reference to FIGS. 2 to 7.

FIG. 2 is a cross-sectional view showing the semiconductor device according to an embodiment of the present invention, wherein the surface of the first metal layer 110 is wet cleaned with either NE14 or DHF in order to improve the adhesion between the first metal layer 110 and the barrier dielectric layer 112.

As shown in FIG. 2, the semiconductor device comprises a first wafer 100 having a first metal layer 110 which is surface treated and a barrier dielectric layer 112. The second wafer 130 is adhered to the first wafer 100 and is formed with a groove 120a on the silicon substrate 120. The adhesion between the first metal layer 110 and the barrier dielectric layer 112 can be tested by the bending system 140.

The first wafer 100 comprises an isolating layer 104 formed on the silicon substrate 102, a first seed layer 108 formed on the barrier metal layer 106, a first metal layer 110 which is wet clean treated using either NE14 or DHF following a CMP process, a barrier dielectric layer 112 formed on the first metal layer 110, a second seed layer 114 formed on the barrier dielectric layer 112, and a second metal layer 116 formed on the second seed layer 114.

The isolating layer 104 is formed of isolating material, for example SiO₂ and is deposited at a thickness of between 500 and 1500 Å.

The barrier metal layer 106 prevents the copper (cu) of the first metal layer 110 from diffusing into the isolating layer 104. The barrier metal layer 106 is formed of a double structure of Ta/TaN or TiSiN at a thickness of between 150 and 200 Å.

The first and second metal layer 110 and 116 are selectively formed on only the upper surface of the first and second seed layers 108 and 114. The first and second seed layers 108 and 114 are formed at a thickness of about 800 Å.

The first and second metal layers 110 and 116 are formed of a metal material, such as copper (cu), which is deposited at a thickness of between 800 and 1000 Å. Next, the surface of the first metal layer 110 is treated by surface treatment methods described more fully below in order to improve the adhesion with barrier dielectric layer 112.

The barrier dielectric layer 112 prevents the diffusion of the copper (cu) of the first metal layer 110 and is formed at a thickness of between 300 and 600 Å.

The second wafer 130 comprises an isolating layer 122 formed on the bottom surface of the silicon substrate 120, a barrier metal layer 124 formed on the bottom surface of the isolating layer 122, and a seed layer 126 formed on the bottom surface of the barrier metal layer 124, which is adhered to the second metal layer 116 of the first wafer 100. Herein, the isolating layer 122 is formed of an isolating material, such as SiO₂, which is deposited at a thickness of 1000 Å. The barrier metal layer 124 prevents the copper (cu) of the second metal layer 116 of the first wafer 100 from diffusing into the isolating layer 104. The barrier metal layer 124 is formed of TiSiN or a double structure of Ta/TaN. The barrier metal layer 124 is formed at a thickness of between 100 and 200 Å. The seed layer 126 is adhered to the second metal layer 116 of the first wafer 100 and is formed at a thickness of 800 Å.

Next, the silicon substrate 120 of the second wafer 130 is formed with a groove 120a in order to test the adhesion between the first metal layer 110 and the barrier dielectric layer 112 using a bending system.

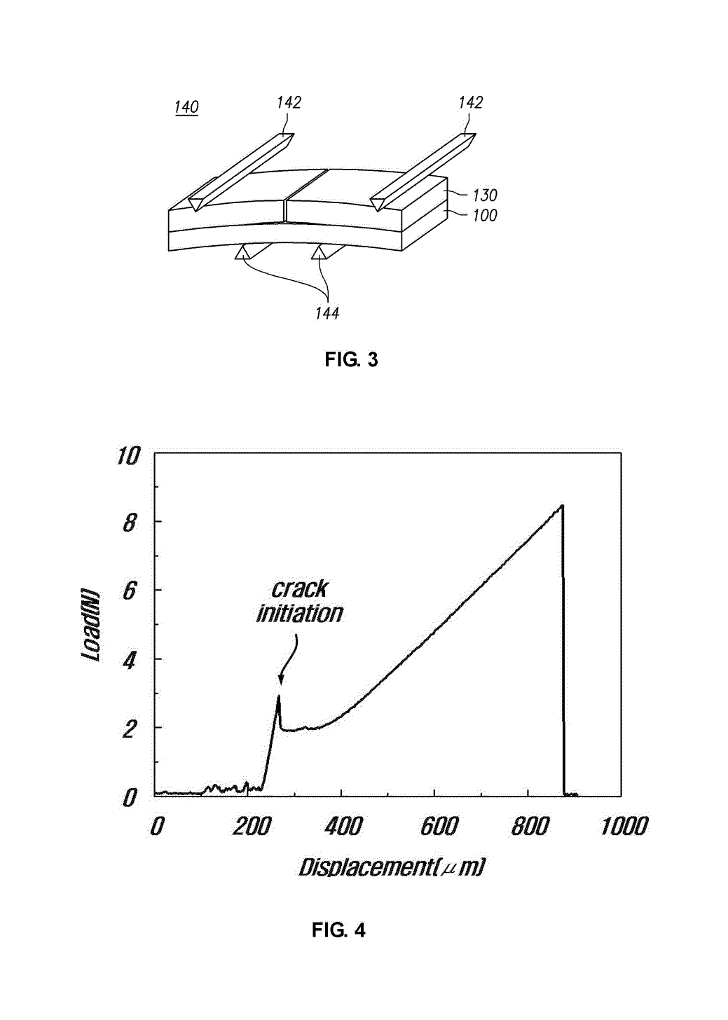

As shown in FIG. 3, the bending system 140 comprises a first pressure part 144 capable of applying a uniform stress to the bottom surface of the first wafer 100 and a second pressure part 142 capable of applying a uniform stress to an upper surface of the second wafer 130. Herein, the first pressure part 140 is installed toward the middle of the first wafer 100 while the second pressure part 142 is installed near the edge of the second wafer 130.

The bending system 140 uses the first pressure part 144 to hold the first and second wafers 100 and 130 in places and then displaces the second pressure part 142 at a speed of −0.8 μm/sec in order to measure the load placed on the wafers as the second pressure part 142 is moved. The relation of the displacement and force measured by the bending system 140 is shown in FIG. 4.

When the bending system 140 applies a load, the groove 120a formed on the surface of the silicon substrate 120 of the second wafer 130 is cracked and broken. At this time, the adhesion between the barrier dielectric layer 112 and the first metal layer can be subjected to various surface treatments as shown in FIG. 4.

After the second wafer 130 is cracked, the various surface treatments such as a plasma treatment, a thermal treatment, a wet cleaning treatment, etc., can be performed on the first metal layer 110.

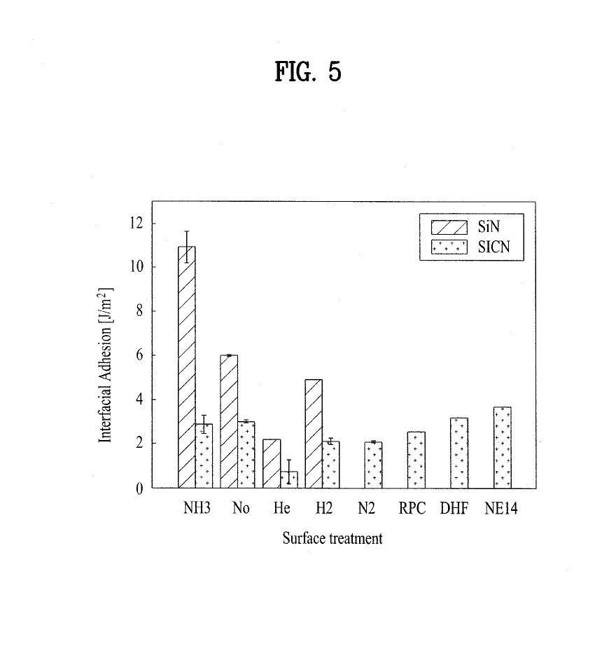

The method of treating the surface according to the present invention was tested, with the results being shown in FIG. 5. Thus, a sample semiconductor with a barrier dielectric layer 112 of SiN was tested and compared to a sample semiconductor with a barrier dielectric layer 112 of SiCN, wherein the surface was treated in order to remove the residues on the first metal layer 110. The surface treatment process comprises a plasma treatment using ammonia (NH₃) and helium (He) and RPC and nitrogen (N₂). A thermal treatment using hydrogen (H₂), the wet cleaning using DHF or NE14 was performed on both sample semiconductors. Thereafter, the adhesion between the first metal layer 110 and the barrier dielectric layer 112 was measured using the bending test.

As shown in FIG. 5, it can be appreciated that the case of forming the barrier dielectric layer 112 with SiN has excellent adhesion as compared to the case of forming it with SiCN. Advantageously, the semiconductor is also formed with a narrow line width. Therefore, one advantage of the invention is a semiconductor made with SiCN, providing a device with a low dielectric constant, which is capable of reducing the RC delay.

As shown in FIG. 5, in samples where the plasma treatment was performed on the first metal layer 110 using ammonia (NH₃), the adhesion was improved.

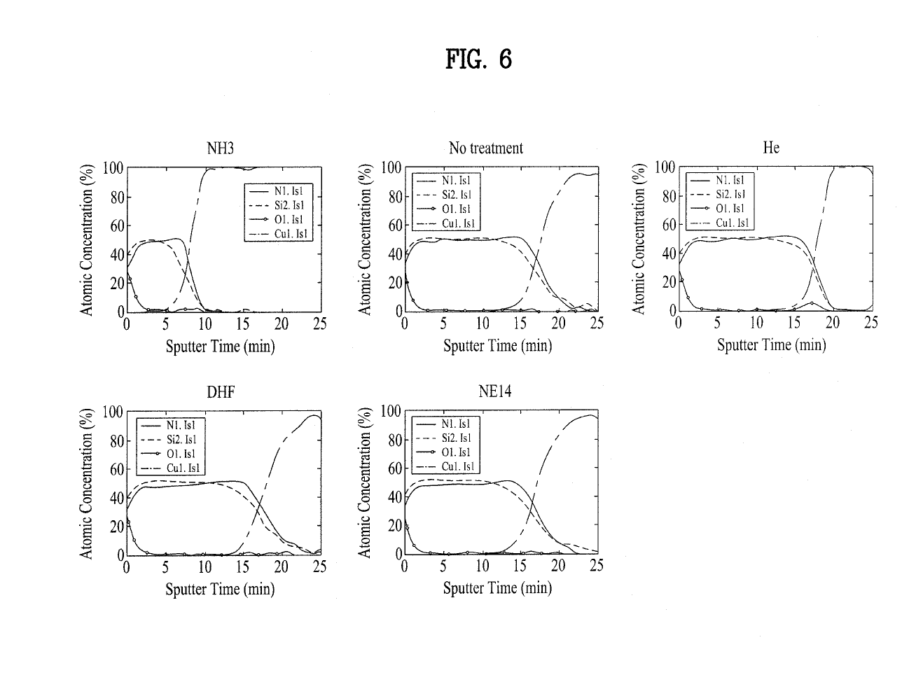

First, when the barrier dielectric layer 112 is formed using silicon nitride (SiN), the plasma treatment using helium (He) and the thermal treatment using hydrogen (H₂) degrades the adhesion compared to the case where the surface treatment is not performed on the first metal layer 110. As shown in FIG. 6, the reason is that there is oxygen (O₁) between the interface of the barrier dielectric layer 112 and the first metal layer 110, which allows the copper to oxidize, forming, for example, CuO or Cu₂O, so that the adhesion is degraded. In contrast, if there is no oxygen present at the interface of the two layers, such as in the case where the surface treatment is not performed on the first metal layer 110, the better adhesion can be obtained. Also, as can be appreciated from FIG. 6, even when the wet cleaning is performed using DHF and NE14, no oxygen component is present at the interface of the two layers, meaning that the adhesion of the first metal layer 110 and the barrier dielectric layer 112 is good.

Meanwhile, when forming the barrier dielectric layer 112 from silicon carbon nitride (SiCN), as shown in FIG. 5, the adhesion between the first metal layer 110 and the barrier dielectric layer 112, wet cleaning the surface using DHF and NE14 improves adhesion by 10 to 30% as compared to the case of the plasma treatment. Herein, the case of the plasma treatment using helium (HE) has the worst adhesion property as compared to other surface treatment methods. And, the case of the thermal treatment using hydrogen (H₂) and the case of the plasma treatment using nitrogen (N₂) and hydrogen (H₂) indicates lower adhesion as compared to the other cases where the plasma treatment process is used.

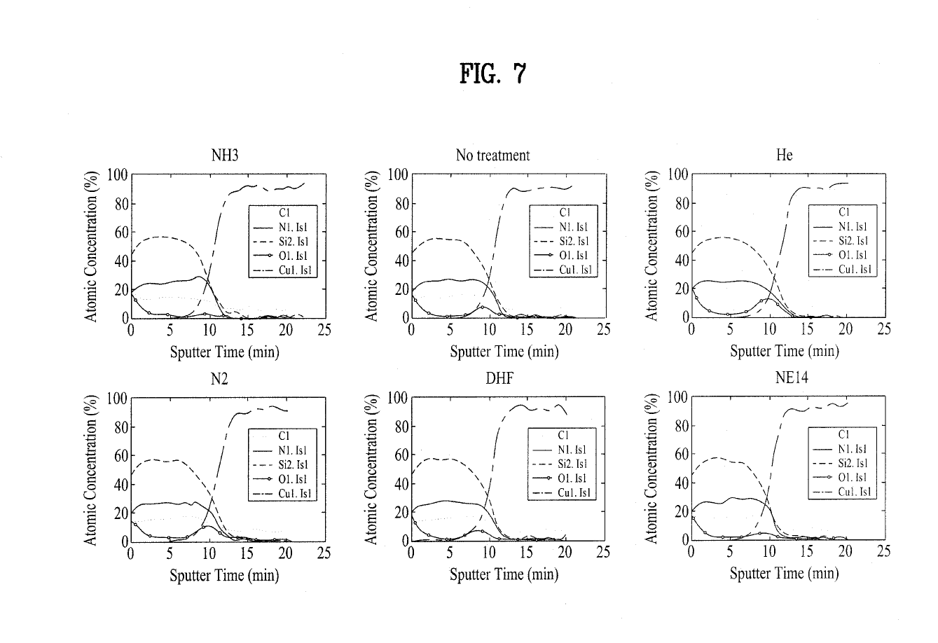

As shown in FIG. 7, the more oxygen (O1) component present at the interface between the first metal layer 110 and the barrier dielectric layer 112 when the plasma treatment process is performed using helium (He), the lower the adhesion. In contrast, when using a wet cleaning process using NE14, there is the least oxygen (O1) present at the interface between the first metal layer 110 and the barrier dielectric layer 112, meaning that excellent adhesion can be obtained.

As can be appreciated from the test, the present invention uses the silicon carbon nitride (SiCN) with dielectric constant lower than the silicon nitride (SiN) as the barrier dielectric layer 12. Moreover, the wet cleaning is performed on the surface of the first metal layer 110 using any one of NE14 and DHF materials that provide the most adhesion between the first metal layer 110 and the barrier dielectric layer 112. Herein, when cleaning the surface of the first metal layer 110 using DHF, fluoric acid diluted with DI water is used, wherein the fluoric acid diluted to between 1:100 and 1:1000 is generally used. Also, after performing the wet cleaning on the surface of the first metal layer 110, the plasma treatment can be performed using ammonia (NH₃).

Although the idea of the present invention has specifically been described according to the preferred embodiments, it should be noted that the embodiments described above are intended to illustrate the present invention, rather than limit it.

In addition, it can be understood by those skilled in the art that various implementations can be made without deviating from the technical idea of the invention.

As described above, the semiconductor device forms a barrier dielectric layer of silicon carbon nitride (SiCN) with low dielectric constant, wherein the surface of the copper wiring is wet cleaned by means of any one of NE14 and DHF, in order to improve the adhesion between the copper wiring and the barrier dielectric layer.

What is claimed is:

1. A semiconductor device comprising:
an isolating layer formed on a silicon substrate;
a barrier metal layer formed on the isolating layer;
a first seed layer formed on the barrier metal layer;
a first metal layer formed on the first seed layer, a surface of the first metal layer being clean-treated using either NE14 or DHF;
a barrier dielectric layer formed on the first metal layer, the barrier dielectric layer being formed of a SiCN material;
a second seed layer formed on the barrier dielectric layer; and
a first wafer comprising a second metal layer formed on the second seed layer.

2. The semiconductor device of claim 1, wherein the isolating layer is formed of SiO₂ at a thickness of between 500 and 1500 Å.

3. The semiconductor device of claim 1, wherein the barrier metal layer is formed of a TiSiN material or is formed in a double structure of Ta/TaN materials.

4. The semiconductor device of claim 1, wherein the first and second metal layer are formed of copper (Cu) at a thickness of between 800 and 1000 Å.

5. The semiconductor device of claim 1, further comprising a second wafer comprising a silicon substrate with a grove formed on the upper surface, a isolating layer formed on a bottom surface of the silicon substrate, a barrier metal layer formed on a bottom surface of the isolating layer, and a seed layer formed on a bottom surface of the barrier metal layer which is adhered to the second metal layer of the first wafer.

6. The semiconductor device of claim 5, further comprising a bending system comprising a first pressure part capable of applying a uniform stress to a bottom surface of the first wafer and a second pressure part capable of applying a uniform stress to an upper surface of the second wafer and moving up and down.

7. A method of forming a semiconductor device, the method comprising:
forming an isolating layer on a silicon substrate;
forming a barrier metal layer on the isolating layer;
forming a first seed layer on the barrier metal layer;
forming a first metal layer on the first seed layer;
clean-treating a surface of the first metal layer using either NE14 or DHF;
forming a barrier dielectric layer of a SiCN material on the first metal layer;
forming a second seed layer on the barrier dielectric layer; and
forming a first wafer comprising a second metal layer on the second seed layer.

8. The method of claim 7, wherein the isolating layer is formed of SiO₂ at a thickness of between 500 and 1500 Å.

9. The method of claim 7, wherein the barrier metal layer is formed of a TiSiN material or is formed in a double structure of Ta/TaN materials.

10. The method of claim 7, wherein the first and second metal layer are formed of copper (Cu) at a thickness of between 800 and 1000 Å.

11. The method of claim 7, further comprising:
forming a second wafer comprising:
a silicon substrate with a grove formed on an upper surface of the silicon substrate;
an isolating layer formed on a bottom surface of the silicon substrate;
a barrier metal layer formed on a bottom surface of the isolating layer;
and a seed layer formed on a bottom surface of the barrier metal layer which is adhered to the second metal layer of the first wafer.

12. The method of claim 11, further comprising applying a stress on the first and second wafers using a bending system comprising a first pressure part capable of applying a uniform stress to a bottom surface of the first wafer and a second pressure part capable of applying a uniform stress to an upper surface of the second wafer and moving up and down.
